(19) United States
(12) Patent Application Publication
(10) Pub. No.: US 2007/0080435 A1
(43) Pub. Date: Apr. 12, 2007

(54) Semiconductor packaging process and carrier for semiconductor package

(76) Inventor: Chun-Hung Lin, Tainan Science-Based Industrial Park (TW)

Correspondence Address: J.C. Patents, Inc., Suite 250, 4 Venture, Irvine, CA, 92618, US

(21) Appl. No.: 11/246,403

(22) Filed: Oct. 6, 2005

(51) Int. Cl. H01L 23/495

(52) U.S. Cl. 257/668

(57) ABSTRACT

A semiconductor packaging process comprising following steps is provided. First, a wiring substrate with a first surface and a second surface is provided. Next, a non-solvent type two-stage thermosetting compound is formed on the first surface of the wiring substrate. The non-solvent type two-stage thermosetting compound is then partially-cured such that a non-solvent type B-stage adhesive layer is formed on the first surface of the wiring substrate to provide a carrier for semiconductor packages. Thereafter, a chip is attached on the first surface of the wiring substrate via the B-stage adhesive layer. Ultimately, the chip is electrically connected to the wiring substrate and an encapsulating material is then formed to seal the chip. A carrier for semiconductor packages used the above mentioned packaging process is also provided.

### BACKGROUND OF THE INVENTION

1. Field of Invention

The present invention relates to a semiconductor packaging process, and more particularly to a SOC (Substrate On Chip) packaging process.

2. Description of Related Art

The so-called “SOC package”, which is Substrate-On-Chip package for short, is referred to a semiconductor package in common use. Semiconductor chips are attached on a substrate with holes, and a plurality of metal bonding wires connect the substrate with the chips via the holes. Normally the substrate is also formed with a plurality of solder balls in a grid array. In the U.S. Pat. No. 6,190,943 entitled “CHIP SCALE PACKAGING METHOD”, a SOC package and a packaging method are disclosed. As shown in FIG. 1, the SOC package 20 comprises a wiring substrate 22, a semiconductor chip 24, and a plurality of spherical solder balls 44. The wiring substrate 22 has an upper surface 30 for attaching the semiconductor chip 24, an underside 38 with the spherical solder balls 44 implanted thereon, and through holes 34 formed in the wiring substrate 22. The semiconductor chip 24 is attached to the upper surface 30 of the wiring substrate 22 by a thermoplastic adhesive layer 28. The through holes 34 of wiring substrate 22 expose the bonding pads 36 on the active surface 26 of semiconductor chip 24 so that the bonding wires 32 may connect the bonding pads 36 of the semiconductor chip 24 and the conductive area 41 of wiring substrate 22 via the through holes 34. The conductive area 41 is provided with a conductive layer 40 formed on the underside 38 of substrate 22. The fringe of the semiconductor chip 24, and each of the through holes 34 of wiring substrate 22 are protected by a passivation layer 42 formed by a non-conducting resin material.

As shown in FIG. 2, the method for fabricating the SOC package 20 disclosed in the U.S. Pat. No. 6,190,943 entitled “CHIP SCALE PACKAGING METHOD” comprises the steps of: (a) providing a wiring substrate 22 with an upper surface 30 which is provided with at least one chip-implanting area 302 including the through holes 34 mentioned above; (b) coating a thermoplastic adhesive layer 28 on the chip-implanting areas 302 by stenciling; (c) attaching chips 24 in the area 302 such that the active surfaces 26 are in contact with the thermoplastic adhesive layer 28, and that the bonding pads 36 are corresponding in location to the through holes 34; (d) heating the wiring substrate 22 and the chips 24 under pressure for a predetermined period of time; (e) forming the bonding wires 32 connecting the conductive area 41 of the wiring substrate 22 with the bonding pads 36 of the chips 24 by wire-bonding via the through holes 34; (f) providing a passivation layer 42 on the fringe of the chip 24 and the through holes 34; (g) implanting a plurality of solder balls 44 in a grid array on the underside 38 of the wiring substrate 22. The SOC package 20 is therefore completed by performing the above-mentioned steps. The thermoplastic adhesive layer 28 mentioned in step (b) is an elastic, semi-liquid, solvent-free thermoplastic silicon rubber. Because it is semi-liquid before attachment, therefore the heating and pressuring conducted the thermoplastic adhesive layer 28 in step (d) is easy to overflow and thus cover the bonding pads 36 of the chip 24, causing failure in package. It is still another disadvantage that after coating of the thermoplastic adhesive layer 28 in step (b), it is unable to pile the wiring substrates 22 for delivery or storage. It is necessary to have the thermoplastic adhesive layer 28 attach to the chips 24 as soon as possible, otherwise, the wiring substrates 22 will be contaminated and adhere to each other, causing difficulties in manufacture.

### SUMMARY OF THE INVENTION

The present invention is directed to provide a carrier for semiconductor packages to improve yields of the die-attaching process.

The present invention is directed to provide a semiconductor packaging process to obtain better fabrication quality.

The present invention is directed to provide a carrier for semiconductor packages. The carrier for semiconductor packages comprises a wiring substrate and a non-solvent type B-stage thermosetting adhesive layer disposed on the wiring substrate.

The present invention is directed to provide a semiconductor packaging process comprising following steps. First, a wiring substrate with a first surface and a second surface is provided. Next, a non-solvent type two-stage thermosetting compound is formed on the first surface of the wiring substrate. The non-solvent type two-stage thermosetting compound is then partially cured such that a non-solvent type B-stage adhesive layer is formed on the first surface of the wiring substrate to provide a carrier for semiconductor packages. Thereafter, a chip is attached on the first surface of the wiring substrate via the B-stage adhesive layer. Ultimately, the chip is electrically connected to the wiring substrate and an encapsulating material is then formed to seal the chip.

After pre-curing the non-solvent type two-stage thermosetting compound, the non-solvent type B-stage adhesive layer is formed. Thus, the carriers of the present invention will not be contaminated and adhere to each other due to the non-solvent type B-stage adhesive layer is gelled. In addition, the carriers are able to pile for delivery or storage, and better operating flexibility is attained in the semiconductor packaging process. Alternately, if the partially cured degree is enough, the B-stage adhesive layer can be solid and non-tacky in room temperature.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a sectional view of a SOC package according to the U.S. Pat. No. 6,190,943 entitled “CHIP SCALE PACKAGING METHOD”.

FIG. 2 is a process flow diagram for fabricating the SOC package in accordance with the U.S. Pat. No. 6,190,943 entitled “CHIP SCALE PACKAGING METHOD”.

FIG. 3A˜FIG. 3E are process flow diagrams of the semiconductor packaging process in accordance with the first embodiment of the present invention.

FIG. 4A˜FIG. 4F are process flow diagrams of the semiconductor packaging process in accordance with the second embodiment of the present invention.

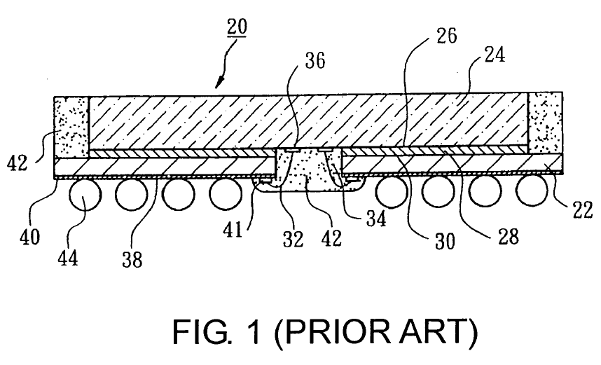

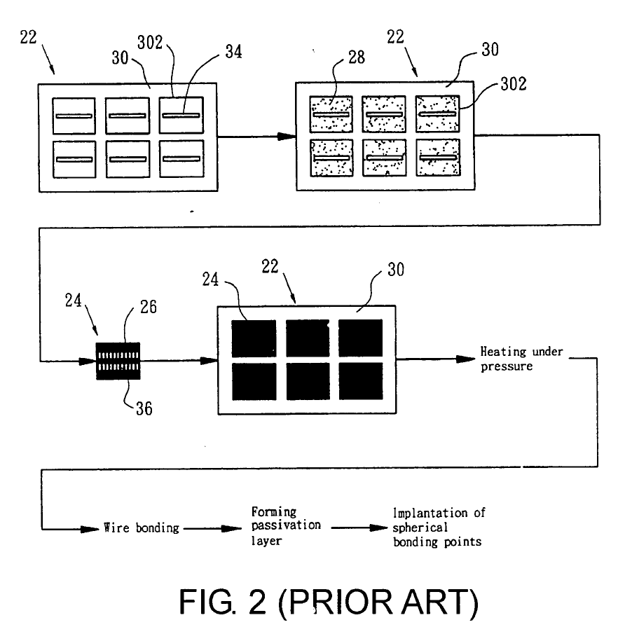

### DESCRIPTION OF THE PREFERRED EMBODIMENTS

First Embodiment

The present invention now will be described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout.

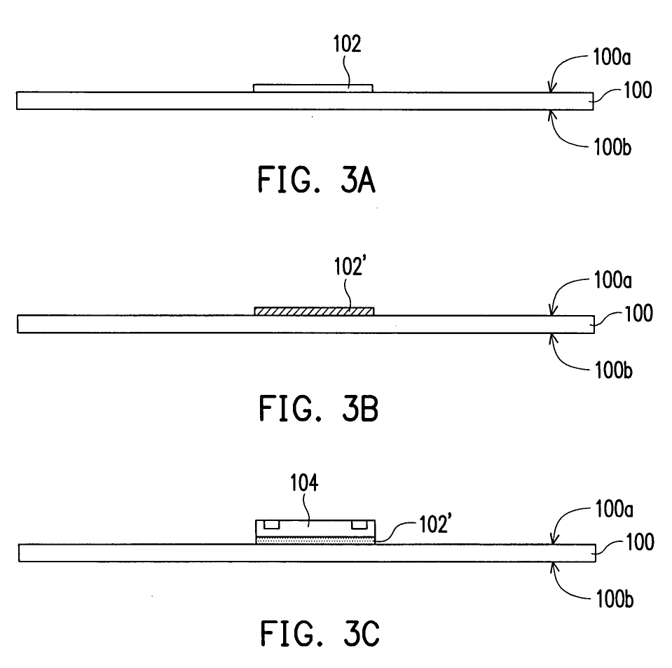

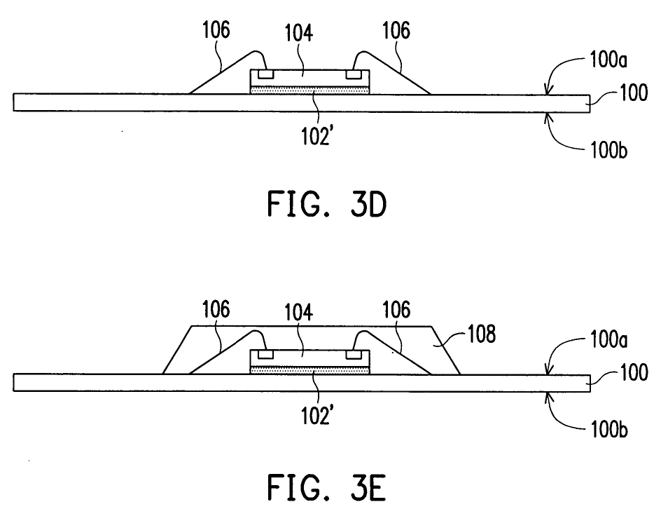

FIG. 3A˜FIG. 3E are process flow diagrams of the semiconductor packaging process in accordance with the first embodiment of the present invention. Referring to FIG. 3A, a wiring substrate 100 with a first surface 100a and a second surface 100b is provided first. The wiring substrate 100 is a printed wiring board, such as FR-4, FR-5, BT, and the like having glass fiber reinforced resin, for example. The first surface 100a of the wiring substrate 100 is formed with a circuit pattern (not shown in figure), such as conductive pads, solder ball pads, and the metal trace which connect the conductive pads with the solder ball pads. Thereafter, a non-solvent type two-stage thermosetting compound 102 is formed on the first surface 100a of the wiring substrate 100. In the present embodiment, the material of the non-solvent type two-stage thermosetting compound 102 comprises polyimide, polyquinolin, benzocyclobutene, or other similar compounds.

Referring to FIG. 3B, the non-solvent type two-stage thermosetting compound 102 is then partially-cured to form a non-solvent type B-stage adhesive layer 102′ on the first surface 100a of the wiring substrate 100. During the pre-curing process, the wiring substrate 100 is heated at a predetermined degree in Celsius, i.e., the wiring substrate 100 can be partially-cured by a thermal curing process. In an alternately embodiment, the wiring substrate 100 can be partially-cured by an UV curing process. After pre-curing process, the non-solvent type B-stage adhesive layer 102′ on the wiring substrate 100 has the B-stage characteristic. Preferably, the non-solvent type B-stage adhesive layer 102′ has no adhesion and is solid in room temperature. Therefore, the wiring substrates 100 are able to pile for delivery or storage in mass. The advantage mentioned above facilitates operation flexibility in the semiconductor packaging process. If necessary, a tacky and gelled B-stage adhesive layer capable of further flowing is used.

Referring to FIG. 3C, at least one chip 104 is attached on the first surface 100a of the wiring substrate 100 via the non-solvent type B-stage adhesive layer 102′. In the present embodiment, a die bonding process for the non-solvent type B-stage adhesive layer 102′ is performed such that the chip 104 is attached on the first surface 100a of the wiring substrate 100. In the present embodiment, the die bonding process is performed by a heating and pressuring process, an UV curing process, or the like. It should be noted that the non-solvent type B-stage adhesive layer 102′ could be still partially cured or fully cured after performing the die bonding process. If necessary, a post curing step may be utilized to fully cure the B-stage adhesive layer 102′ by thermal or UV as the B-stage adhesive layer 102′ is still partially cured after die bonding process.

Referring to FIG. 3D, after the die bonding process, the chip 104 is electrically connected to the wiring substrate 100 by a plurality of bonding wires 106. In the present embodiment, the bonding wires 106 such as gold wires are formed by wire bonders utilized in wire-bonding process.

Referring to FIG. 3E, an encapsulant 108 is formed to encapsulate (or seal) the chip 104 on the wiring substrate 100. Preferably, the bonding wires 106 are also encapsulate (or seal) by the encapsulant 108. In the present embodiment, the encapsulant 108 is formed by molding or other similar processes. Specifically, the non-solvent type B-stage adhesive layer 102′ will be fully cured during encapsulation process if the non-solvent type B-stage adhesive layer 102′ is still partially cured before the encapsulation process.

Second Embodiment

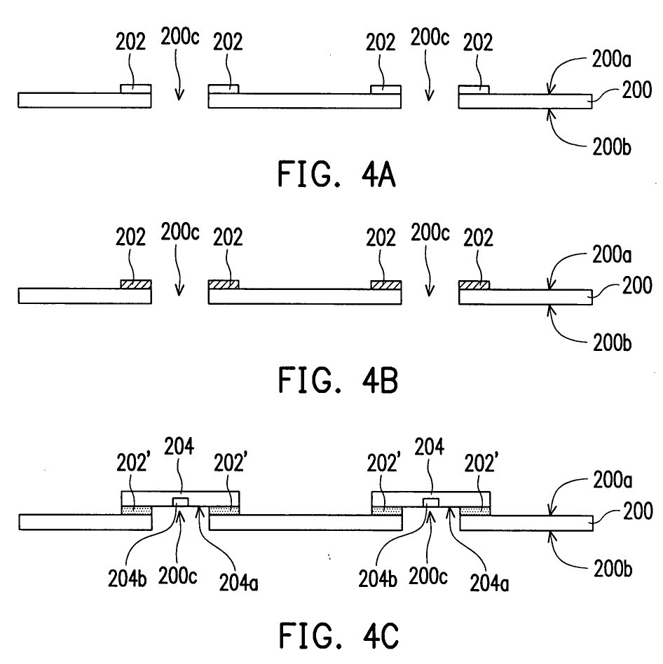

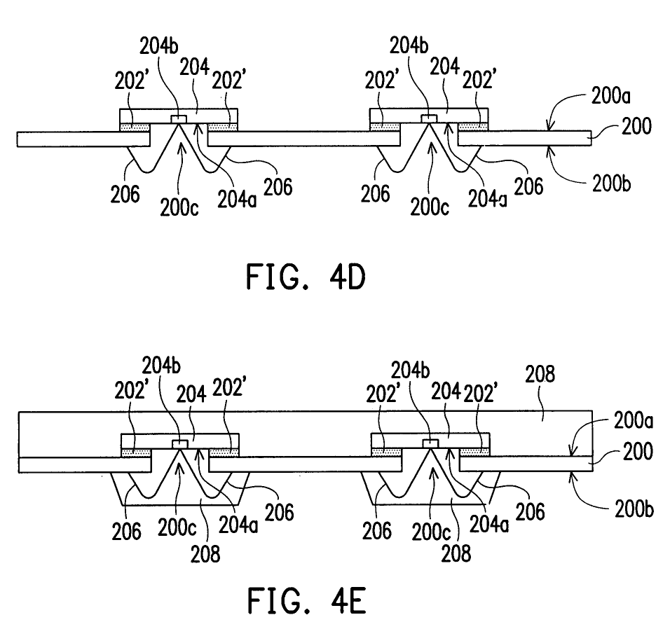

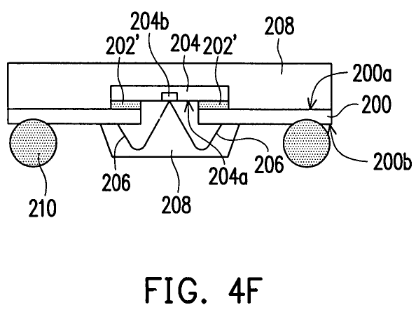

FIG. 4A˜FIG. 4E are process flow diagrams of the semiconductor packaging process in accordance with the second embodiment of the present invention. A substrate on chip (SOC) packaging process utilizing the non-solvent type B-stage adhesive layer is described herein.

Referring to FIG. 4A, a wiring substrate 200 with a first surface 200a and a second surface 200b is provided first. In the present embodiment, the detail structure of the wiring substrate 200 is substantially identical with the wiring substrate 100 illustrated in FIG. 3A except that the wiring substrate 200 has at least one through hole 200c. Then, a non-solvent type two-stage thermosetting compound 202, which is located at the side of the through hole 200c, is formed on the first surface 100a of the wiring substrate 200.

Referring to FIG. 4B, the non-solvent type two-stage thermosetting compound 202 is then partially-cured to form a non-solvent type B-stage adhesive layer 202′ on the first surface 200a of the wiring substrate 200. During the pre-curing process, the wiring substrate 200 is heated at a predetermined degree in Celsius, i.e., the wiring substrate 200 can be partially-cured by a thermal curing process. In an alternately embodiment, the wiring substrate 200 can be partially-cured by an UV curing process. After pre-curing process, the non-solvent type B-stage adhesive layer 202′ on the wiring substrate 200 has the B-stage characteristic. Preferably, the non-solvent type B-stage adhesive layer 202′ has no adhesion and is solid in room temperature. Therefore, the wiring substrates 200 are able to pile for delivery or storage in mass. The advantage mentioned above facilitates operation flexibility in the semiconductor packaging process. If necessary, a tacky and gelled B-stage adhesive layer capable of further flowing is used.

Referring to FIG. 4C, at least one chip 104 is provided and attached on the first surface 200a of the wiring substrate 200 via the non-solvent type B-stage adhesive layer 202′. In the present embodiment, a die bonding process for the non-solvent type B-stage adhesive layer 202′ is performed such that the chip 204 is attached on the first surface 200a of the wiring substrate 200. In the present embodiment, the die bonding process is performed by a heating and pressuring process, an UV curing process, or the like. It should be noted that the non-solvent type B-stage adhesive layer 202′ could be still partially cured or fully cured after performing the die bonding process. If necessary, a post curing step may be utilized to fully cure the B-stage adhesive layer 202′ by thermal or UV as the B-stage adhesive layer 202′ is still partially cured after die bonding process.

As shown in FIG. 4C, the chip 204 comprises an active surface 204a and a plurality of bonding pads 204b on the active surface 204a. The active surface 204a of the chip 204 is adhered with the first surface 200a of the wiring substrate 200 through the non-solvent type B-stage adhesive layer 202′. After die-attaching process, the bonding pads 204b of the chip 204 are exposed by the through hole 200c of the wiring substrate 200.

Referring to FIG. 4D, after the die bonding process, the chip 204 is electrically connected to the wiring substrate 200 by a plurality of bonding wires 206. In the present embodiment, the bonding wires 206 such as gold wires are formed by wire bonders utilized in wire-bonding process. As shown in FIG. 4D, the bonding wires 206 passing the through hole 200c are electrically connected between the bonding pads 204b of the chip 204 and the wiring substrate 200.

Referring to FIG. 4E, an encapsulant 208 is formed to encapsulate (or seal) the chip 204 on the wiring substrate 200. Preferably, the bonding wires 206 are also encapsulate (or seal) by the encapsulant 208. As shown in FIG. 4E, the encapsulant 208 not only fills into the through hole 200c of the wiring substrate 200, but also covers the first surface 200a and a portion of the second surface 200b. In the present embodiment, the encapsulant 208 is formed by molding or other similar processes. Specifically, the non-solvent type B-stage adhesive layer 202′ will be fully cured during encapsulation process if the non-solvent type B-stage adhesive layer 202′ is still partially cured before the encapsulation process.

Referring to FIG. 4F, after forming the encapsulant 208, a plurality of solder balls 210 could be implanted on the second surface 200b of the wiring substrate 200. Ultimately, a sawing process is then performed to obtain a plurality of SOC packages 300.

In the present invention, a non-solvent type B-stage adhesive layer is used as an adhesive film for the wiring substrate and chip such that the bonding pads of chip are not covered by the adhesive film. The present invention also increases the SOC packaging efficiency and ability to pile for delivery or storage. In addition, better operation flexibility is attained in the packaging process of the present invention.

The foregoing description of the preferred embodiment of the present invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A semiconductor packaging process, comprising:
providing a wiring substrate with a first surface and a second surface;
forming a non-solvent type two-stage thermosetting compound on the first surface of the wiring substrate;
partially-curing the non-solvent type two-stage thermosetting compound such that a non-solvent type B-stage adhesive layer is formed on the first surface of the wiring substrate;
attaching a chip on the first surface of the wiring substrate via the non-solvent type B-stage adhesive layer;
electrically connecting the chip to the wiring substrate; and
forming an encapsulant to encapsulate the chip on the wiring substrate.

2. The semiconductor packaging process according to claim 1, wherein the wiring substrate further comprises a through hole.

3. The semiconductor packaging process according to claim 2, wherein the non-solvent type two-stage thermosetting compound is formed by the side of the through hole.

4. The semiconductor packaging process according to claim 2, wherein the chip comprises an active surface and a plurality of bonding pads on the active surface, the active surface of the chip is adhered with the first surface of the wiring substrate through the non-solvent type B-stage adhesive layer, and the bonding pads of the chip are exposed by the through hole of the wiring substrate.

5. The semiconductor packaging process according to claim 2, wherein the bonding pads exposed by the through hole is electrically connected to the wiring substrate via a plurality of bonding wires formed by wire-bonding process.

6. The semiconductor packaging process according to claim 5, wherein the encapsulant is formed in the through hole to encapsulate the chip and the bonding wires.

7. The semiconductor packaging process according to claim 1, wherein the non-solvent type two-stage thermosetting compound comprises polyimide, polyquinolin, or benzocyclobutene.

8. The semiconductor packaging process according to claim 1, wherein the non-solvent type B-stage adhesive layer is solid and/or has no adhesion in room temperature.

9. The semiconductor packaging process according to claim 1, wherein the non-solvent type B-stage adhesive layer is tacky and gelled.

10. The semiconductor packaging process according to claim 1, wherein the non-solvent type two-stage thermosetting compound is partially-cured by an UV curing process or a thermal curing process.

11. The semiconductor packaging process according to claim 1, wherein the chip is attached on the first surface of the wiring substrate by further curing the non-solvent type B-stage adhesive layer.

12. The semiconductor packaging process according to claim 11, wherein the non-solvent type B-stage adhesive layer is fully cured when the chip is attached on the first surface of the wiring substrate.

13. The semiconductor packaging process according to claim 11, wherein the non-solvent type B-stage adhesive layer is not fully cured when the chip is attached on the first surface of the wiring substrate.

14. The semiconductor packaging process according to claim 13, wherein the non-solvent type B-stage adhesive layer is fully cured by a UV or a thermal post curing process.

15. The semiconductor packaging process according to claim 13, wherein the non-solvent type B-stage adhesive layer is fully cured when the encapsulant is formed to encapsulate the chip on the wiring substrate.

16. The semiconductor packaging process according to claim 1, wherein the chip is electrically connected to the wiring substrate by wire-bonding process.

17. The semiconductor packaging process according to claim 1, wherein the encapsulant is formed by molding.

18. The semiconductor packaging process according to claim 1, further comprising forming a plurality of solder balls on the second surface of the wiring substrate after forming the encapsulant.

19. A carrier for semiconductor packages, comprising:
a wiring substrate; and
a non-solvent type B-stage thermosetting adhesive disposed on the wiring substrate.

20. The carrier according to claim 19, wherein the wiring substrate comprises a through hole and the non-solvent type two-stage thermosetting compound is disposed by the side of the through hole.

21. The carrier according to claim 19, wherein the non-solvent type B-stage adhesive layer is solid and/or has no adhesion in room temperature.

22. The carrier according to claim 19, wherein the non-solvent type B-stage adhesive layer is tacky and gelled.

23. The carrier according to claim 19, wherein the non-solvent type B-stage adhesive layer comprises polyimide, polyquinolin, or benzocyclobutene.
